(19) United States
(12) Patent Application Publication
(10) Pub. No.: US 2026/0361008 A1
(43) Pub. Date: Nov. 12, 2026

(54) HIGH-TEMPERATURE SUPERCONDUCTING (HTS) TERMINATION FOR DATACENTER POWER TRANSMISSION

(71) Applicant: Microsoft Technology Licensing, LLC, Redmond, WA (US)

(72) Inventors: Ruslan NAGIMOV, Snohomish, WA (US); Eric Clarence PETERSON, Woodinville, WA (US)

(21) Appl. No.: 19/205,552

(22) Filed: May 12, 2025

(51) Int. Cl. H01R 4/68; H01B 12/08; H01B 12/16; H01R 13/00; H01R 13/533; H01R 13/645; H01R 25/16; H01R 105/00; H05K 5/02; H05K 7/20

(52) U.S. Cl. CPC H01R 4/68; H01B 12/08; H01B 12/16; H01R 13/005; H01R 13/533; H01R 13/645; H01R 25/162; H05K 5/0247; H05K 7/20327; H05K 7/20372; H05K 7/20827; H01R 2105/00

(57) ABSTRACT

Compact high-temperature superconducting (HTS) power cables can be used to resolve a power delivery bottleneck caused by high deployment densities of GPU racks within a datacenter. HTS cables are cooled to cryogenic temperatures to achieve an HTS characteristic. However, incorporating a transition from cold HTS cables to warm copper cables for powering GPU racks is challenging. To make good electrical contact, the cross sectional contact area for the transition is maximized. To minimize thermal transfer across the transition, the cross sectional contact area for the transition is minimized. The presently disclosed rack busbar termination device achieves a HTS cable to copper cable connection with a reduced footprint by integrating the termination device with connected rack busbars. A “floating busbar” inside the rack busbar termination device enables an effective thermal isolation of the cryogenically cooled HTS conductors from the connected relatively warm server infrastructure.

### BACKGROUND

High-temperature superconducting (HTS) power technology utilizes materials that superconduct at temperatures above 77 Kelvin (the boiling point of liquid nitrogen) to enable efficient and high-capacity power transmission, offering a potential for efficiently delivering relatively large current AC or DC power at relatively low voltages to power high deployment density datacenter designs. HTS cables use superconducting materials to transport electricity, even low voltage AC or DC power, with minimal losses and therefore may provide higher power capacity and efficiency over conventional copper cables.

### SUMMARY

Implementations described and claimed herein provide a high-temperature superconducting (HTS) termination comprising an HTS cable including a first array of conductor ends; a first cold busbar, the first array of conductor ends connected to the first cold busbar; a first warm busbar; a first array of braided links connecting the first cold busbar to the first warm busbar; and a vacuum shell enclosing the first array of conductor ends, the first cold busbar, the first warm busbar, and the first array of braided links.

Implementations described and claimed herein further provide a method of transmitting power from a high-temperature superconducting (HTS) cable to a server rack using a HTS termination. The method comprises conducting electricity from an array of conductor ends extending from the HTS cable to a cold busbar within the HTS termination; conducting electricity from the cold busbar to a warm busbar using an array of braided links connecting the cold busbar to the warm busbar within the HTS termination, wherein a vacuum shell encloses the array of conductor ends, the cold busbar, the warm busbar, and the array of braided links within the HTS termination; and conducting electricity from the warm busbar within the HTS termination to a rack busbar outside of the HTS termination, the rack busbar to power the server rack.

Other implementations are also described and claimed herein.

### BRIEF DESCRIPTION OF THE DRAWINGS

FIG. 1 illustrates a server rack connected to a pair of high-temperature superconducting (HTS) cables using example HTS terminations, respectively, according to the presently disclosed technology.

FIG. 2 illustrates a section of an example HTS termination according to the presently disclosed technology to be selectively connected to one of a pair of rack busbars attached to a rear of a server rack.

FIG. 3 illustrates a section of an example HTS termination according to the presently disclosed technology.

FIG. 4 illustrates a row of server racks connected to high-temperature superconducting (HTS) cables and a HTS main using example HTS terminations according to the presently disclosed technology.

FIG. 5 illustrates example operations for transmitting power from an HTS cable to a server rack using a HTS termination.

### DETAILED DESCRIPTION

Datacenter designs for artificial-intelligence (AI) applications benefit from high deployment densities due to the nature of AI-training workloads. Specifically, distributed AI model training requires synchronous operation of hundreds of thousands of graphical processing units (GPUs), organized in GPU clusters, and such training is sensitive to network latencies. Therefore, distributed AI model training benefits from high deployment densities within a datacenter design to minimize network latency.

A constraining factor for densification of GPU clusters is the power draw of such GPU racks, which may exceed 1 MW per GPU rack. This complicates power distribution systems as delivering 1 MW @ 500V requires 2,000 A of current. To maintain a reasonable transmission loss, such a high current requires an increased traditional copper cable cross-section to a point where the cable cross-section impedes further growth of deployment density.

Compact high-temperature superconducting (HTS) power cables can be used to resolve this power delivery bottleneck. HTS cables are cooled to cryogenic temperatures (approximately 77K, the boiling point of liquid nitrogen or 70K-100K) to achieve an HTS characteristic. However, incorporating a transition from cold HTS cables to warm copper cables for powering GPU racks is challenging. To make good electrical contact, the cross sectional contact area for the transition should be maximized. To minimize thermal transfer across the transition, the cross sectional contact area for the transition should be minimized. These conflicting design requirements yield large HTS cable to copper cable termination devices that occupy a large amount of space in the datacenter.

The presently disclosed technology presents a rack busbar termination device that achieves the HTS cable to copper cable connection with a reduced footprint by integrating the termination device with connected rack busbars. This compact termination device utilizes an existing infrastructure footprint, while maximizing space utilization within that footprint. A “floating busbar” inside the presently disclosed termination device enables an effective thermal isolation of the cryogenically cooled HTS conductors from the connected relatively warm server infrastructure. The presently disclosed termination device may also include “quick-connect” feature that allow for fast mounting and dismounting individual server racks from a row of server racks using the termination device.

Accordingly, the presently disclosed technology is directed to an HTS termination device for electronic systems, such as GPU clusters and associated electronic components, such as servers, networking devices, power conversion devices, and data storage devices. Such technology may be useful in data centers as numerous power hungry GPU clusters may be present and a HTS power supply may be desired or practically necessary to supply sufficient power to the GPU clusters within the datacenter footprint the GPU clusters occupy.

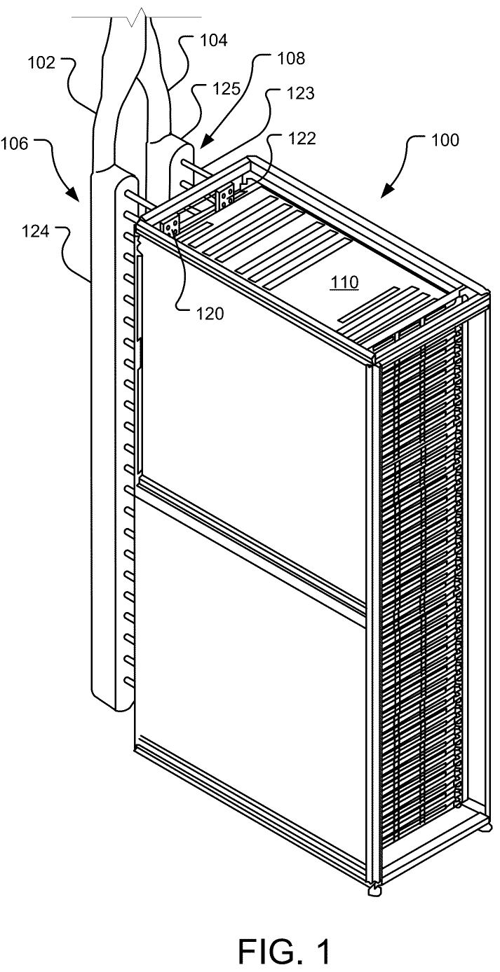

FIG. 1 illustrates a server rack 100 connected to a pair of high-temperature superconducting (HTS) cables 102, 104 using example HTS terminations 106, 108, respectively, according to the presently disclosed technology. The server rack 100 is a standardized frame or enclosure for mounting multiple electronic equipment modules, such as servers (see e.g., server 110), networking devices, and power conversion devices. Each of the servers may be tasked with a variety of computing tasks, including by not limited to distributed AI model training, which requires synchronous operation of hundreds of thousands of graphical processing units (GPUs), organized in GPU clusters. The server rack 100 may be one of many within a datacenter room. There may also be numerous datacenter rooms within a datacenter facility.

The server rack 100 includes a pair of rack busbars 120, 122, which are only visible from the top of the server rack 100 as a top cover (not shown) of the server rack 100 is removed in FIG. 1 for illustration purposes. The rack busbars 120, 122 extend vertically and generally parallel at a rear of the server rack 100 and serve as power connection conductors for powering the server rack 100. While two rack busbars 120, 122 are shown in FIG. 1 for a two-conductor power connection (e.g., positive and neutral for an AC or DC power supply), in other implementations, an additional similar rack busbar may be included for a three-conductor power connection (e.g., one for each of three phases for a three phase AC power supply). Further, the rack busbars 120, 122 are illustrated in FIG. 1 as perforated plates so that the HTS terminations 106, 108 may be bolted to the rack busbars 120, 122, respectively. Other implementations may utilize another clamped, magnetic, or other electrically conductive attachment between the HTS terminations 106, 108 and the rack busbars 120, 122, respectively, of any size and arrangement.

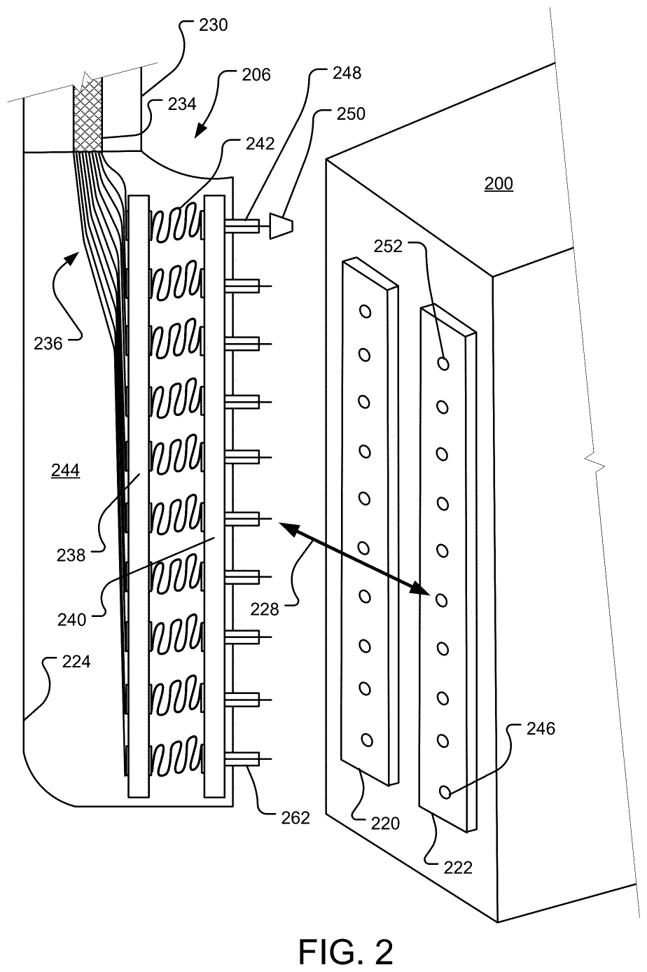

The HTS terminations 106, 108 may be connected to the rack busbars 120, 122 via an array of electrically conductive vacuum feedthroughs (e.g., vacuum feedthrough 123). While the conductive vacuum feedthroughs are illustrated as long cylindrical structures in FIG. 1 so that they are visible, in practice the vacuum feedthroughs may not be visible between the HTS terminations 106, 108 and the rack busbars 120, 122. The vacuum feedthroughs may be an array of vacuum feedthrough pins used to selectively connect warm busbars (not shown, see e.g., warm busbar 240 of FIG. 2) within the HTS terminations 106, 108 through their respective vacuum shells 124, 125 and to the rack busbars 120, 122. In other implementations, the warm busbars protrude from their respective vacuum shells 124, 125. Protruding portion(s) of the warm busbars selectively connect to the rack busbars 120, 122 directly without use of separate conductive vacuum feedthroughs.

FIG. 2 illustrates a section of an example HTS termination 206 according to the presently disclosed technology to be selectively connected to one or both of a pair of rack busbars 220, 222 attached to a rear of a server rack 200. The server rack 200 is a standardized frame or enclosure for mounting multiple electronic equipment modules, such as servers. The server rack 200 may be one of many within a datacenter room.

The rack busbars 220, 222 extend vertically and generally parallel at a rear of the server rack 200 and serve as power connection conductors for powering the server rack 200. While two rack busbars 220, 222 are shown in FIG. 2 for a two-conductor power connection, in other implementations, an additional similar rack busbar may be included for a three-conductor power connection. Further, the rack busbars 220, 222 are illustrated in FIG. 2 as perforated plates so that the HTS termination 206 may be selectively bolted to one of the rack busbars 220, 222, as illustrated by arrow 228. A second duplicate half of the HTS termination 206 or a second HTS termination overall (e.g., a duplicate of HTS termination 206) is bolted to the other of the rack busbars 220, 222 and may have similar features as described in detail below. Other implementations may utilize another clamped, magnetic, or other electrically conductive attachment between the HTS terminations and the rack busbars 220, 222, respectively, of any size and arrangement.

The HTS termination 206 is the terminal end of an HTS cable 230 that is cooled to cryogenic temperatures to achieve an HTS characteristic to carry high-current power to the server rack 200 with low resistance losses. The HTS termination 206 transitions from the cold (cryogenic, defined generally as −195.79 °C (77.36 K) to −50 °C (223 K)) HTS cable 230 to the warm (at least room temperature, defined generally as 15 °C to 25 °C, or warmer) rack busbars 220, 222 with good electrical contact, but minimized thermal transfer across the transition in a relatively small space. While the datacenter room may be maintained at generally room temperature (defined generally as 15 °C to 25 °C), the rack busbars 220, 222 will often operate at a warmer temperature due to the heat generated by the attached server rack 200.

The HTS cable 230 includes a set of conductors 234 that is fanned out into an array of conductor ends 236, each of which are soldered or otherwise electrically connected, to a cold busbar 238 within the HTS termination 206. In some implementations, the HTS cable 230 takes the form of a layered tape, with the array of conductor ends 236 being tape ends. In other implementations, the HTS cable 230 takes the form of a coaxially layered cable, with the array of conductor ends 236 being cable ends. Either implementation may utilize rare-earth barium copper oxide (ReBCO) as the layered conductor. Other implementations may utilize different conductor arrangements or materials for the HTS cable 230, its set of conductors 234, and the conductor ends 236.

The cold busbar 238 is electrically connected to a warm busbar 240, also within the HTS termination 206. This connection is achieved using an array of braided links (e.g., braided link 242) that have good electrical conductivity, but limited thermal conductivity due to extended lengths of individual strands of the braided links. This allows the cold busbar 238 to be electrically connected to the warm busbar 240, while limiting thermal transfer between the cold busbar 238 and the warm busbar 240 within the HTS termination 206. Opposing ends of each of the braided links are generally soldered to the cold busbar 238 and the warm busbar 240, however, other mechanisms may be used to connect the cold busbar 238 and the warm busbar 240 using the braided links (e.g., welded, glued, chemically bonded, clipped, bolted, or other mechanical connections). As a result, the warm busbar 240 operates at a temperature between that of the cold busbar 238 (cryogenic, or warmer) and the rack busbars 220, 222 (room temperature, or warmer).

The terminal end of the set of conductors 234, including the array of conductor ends 236, as well as the cold busbar 238, the braided links, and the warm busbar 240 are all enclosed within a vacuum shell 224. The vacuum shell 224 provides a space 244 between the set of conductors 234, including the array of conductor ends 236, as well as the cold busbar 238, the braided links, and the warm busbar 240 for both thermal and electrical insulation from an exterior of the HTS termination 206. The vacuum shell 224 also provides mechanisms for mechanical suspension of cold masses 234, 236, 238, 240, 242 with minimal thermal coupling between the cold masses and the warm vacuum shell 224 via internal support structures made of materials with low thermal conductivity. Also present, but not shown in FIG. 2, is a cooling infrastructure circulating coolant and maintaining the set of conductors 234 at their operating temperature, generally below 77K.

The HTS termination 206 is connected to the rack busbar 222 via an array of electrically conductive vacuum feedthroughs (e.g., vacuum feedthrough 262) that protrude through the vacuum shell 224. The conductive vacuum feedthroughs are conductive members (e.g., pins, rods, or other electrically conductive elements), each surrounded by an insulating seal (e.g., epoxy, plastic, ceramic, or glass) that maintains a vacuum seal with the surrounding vacuum shell 224. The conductive vacuum feedthroughs are used to selectively connect the warm busbar 240 to the rack busbar 222 through the vacuum shell 224. The array of conductive vacuum feedthroughs is a matched set to an array of apertures (e.g., aperture 246) in the rack busbar 222. The allows the conductive vacuum feedthroughs to be screwed or bolted to the rack busbar 222. These screwed or bolted attachments permit the HTS termination 206 to be selectively connected to the rack busbar 222. In some implementations, these screwed or bolted (or clamped) attachments allow the HTS termination 206 to function as a “quick-connect” for fast mounting and dismounting individual server racks from a row of server racks using a singular (or fewer) clamped or other connections. This is technically advantageous in that server racks may be quickly put into service and taken out of service with minimal downtime.

Conductive vacuum feedthrough 248 also includes an alignment pin 250 that corresponds to alignment aperture 252. The alignment pin 250 and alignment aperture 252 is used to align the HTS termination 206 with the rack busbar 222 prior to screwing or bolting the conductive vacuum feedthroughs to the rack busbar 222. In some implementations, the alignment pin 250 also serves as a conductive vacuum feedthrough, as shown. In other implementations, the alignment pin 250 is a separate structure. Similarly, the alignment aperture 252 may also serve as one of the conductive apertures, or not. Further, while only one alignment pin and corresponding alignment aperture 252 is shown in FIG. 2, multiple pairings of alignment and alignment aperture may be used to adequately align the HTS termination 206 with the rack busbar 222 prior to screwing or bolting the conductive vacuum feedthroughs to the rack busbar 222. In still further implementations, the placement of the alignment pin 250 on the HTS termination 206 and the alignment aperture 252 on the rack busbar 222 may be reversed.

All of the conductive vacuum feedthroughs and corresponding apertures may be used for alignment, as well as making conductive contact between the warm busbar 240 and the rack busbar 222. In other implementations, the warm busbar 240 protrudes through the vacuum shell 224 and the protruding portion(s) of the warm busbar 240 selectively connects to the rack busbar 222 directly without use of the separate conductive vacuum feedthroughs.

Copper, or a copper containing alloy, may be used for the conducting components of the HTS termination 206 due to its mix of availability, cost, and electrical conductivity. Other possible materials include gold, silver, alloys thereof, and steel. Selection of an appropriate material for the conducting components of the HTS termination 206 is an optimization problem with multiple constraints, such as the foregoing.

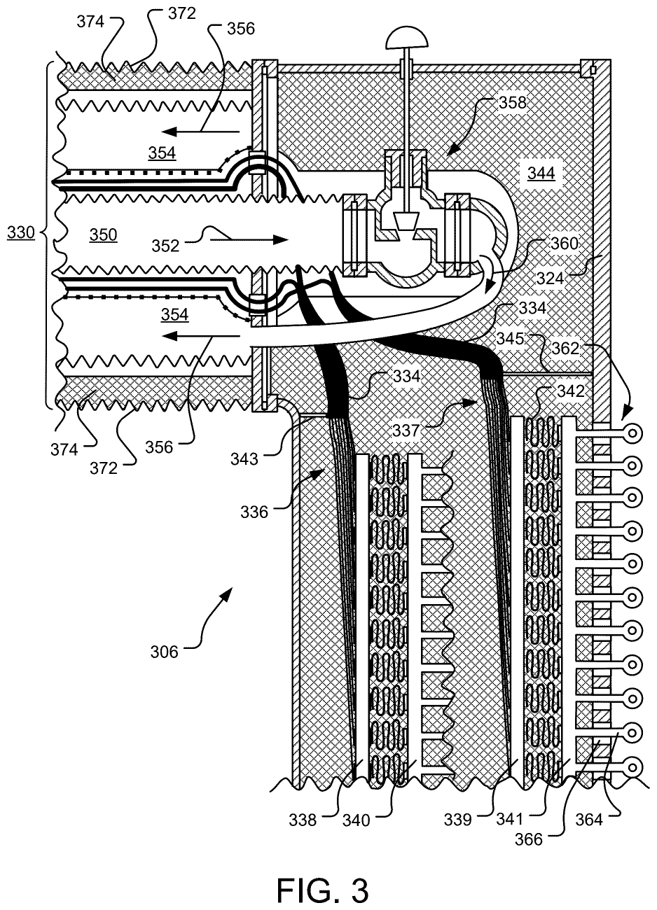

FIG. 3 illustrates a section of an example HTS termination 306 according to the presently disclosed technology. The HTS termination 306 is to be selectively connected to a pair of rack busbars (not shown, see e.g., rack busbars 220, 222 of FIG. 2) attached to a rear of a server rack (also not shown, see e.g., server rack 200 of FIG. 2). The rack busbars serve as power connection conductors for powering the server rack. The HTS termination 306 is the terminal end of an HTS cable 330 that is cooled to cryogenic temperatures to achieve an HTS characteristic to carry high-current power to the server rack with low resistance losses. The HTS termination 306 transitions from the cold (cryogenic) HTS cable 330 to the warm (room temperature or warmer) rack busbars with good electrical contact but minimized thermal transfer across the transition in a relatively small space.

The HTS cable 330 is cryogenically cooled by circulating a coolant that may have a normal boiling point below 120K (e.g., liquefied gases, such as helium, hydrogen, neon, nitrogen, and oxygen), or cold gases or other cryogens, such as liquid methane through coolant supply 350, as illustrated by arrow 352, and back through coolant return 354, as illustrated by arrows 356. Each of the coolant supply 350 and the coolant return 354 extend lengthwise down the HTS cable 330. The coolant is in thermally conductive contact with an arrangement of conductors 334 within the HTS cable 330 that also extends lengthwise down the HTS cable 330. A vacuum jacket 372 extends lengthwise down the HTS cable 330 and surrounds the conductors 334, the coolant supply 350, and the coolant return 354. The vacuum jacket 372 provides a vacuum space 374 for thermal and/or electrical insulation from an exterior of the HTS cable 330.

A cooling action of the coolant allows for the conductors 334 to remain at a stable cryogenic temperature within the HTS cable 330, thereby achieving the HTS characteristic. This allows for a high-current electrical flow through the HTS cable 330 within minimal resistance losses. A heat exchanger (not shown) allows for heat rejection from the coolant before re-entering the HTS cable 330 via the coolant supply 350. The HTS cable 330 is depicted in a coaxial format, with the conductors 334 residing coaxially between the central coolant supply 350 and outside coolant return 354. Other implementations may not be coaxial and place the conductors 334, coolant supply 350, and coolant return 354 differently then than shown in FIG. 3.

A control valve 358 may be used to control the flow rate of the coolant through the HTS cable 330, illustrated by arrow 360, to maintain a desired temperature of the conductors 334, as well as a phase or temperature change of the coolant as it flows through the HTS cable 330. The control valve 358 may be manually or automatically controlled via sensors and a feedback loop. In other implementations, a precisely selected orifice is used in place of the control valve 358 to pre-set the flow rate of the coolant through the HTS cable 330 based on a pre-selected use case of the HTS cable 330.

The conductors 334 are fanned out into a pair of array of conductor ends 336, 337, each of which are soldered or otherwise electrically connected, to one of cold busbars 338, 339 within the HTS termination 306. The HTS termination 306 receives the array of conductor ends 336, 337 in this manner. The pair of array of conductor ends 336, 337 are each for one of a two-conductor power connection. In other implementations, an additional similar array of conductor ends may be included for a three-conductor power connection.

The cold busbars 338, 339 are electrically connected to warm busbars 340, 341, respectively, within the HTS termination 306. This connection is achieved using two arrays of braided links (e.g., braided link 342) that have good electrical conductivity, but limited thermal conductivity due to lengths of individual strands of the braided links. This allows the cold busbars 338, 339 to be electrically connected to the warm busbars 340, 341, while limiting thermal transfer between the cold busbars 338, 339 and the warm busbars 340, 341, respectively. Opposing ends of each of the braided links are generally soldered to one of the cold busbars 338, 339 and one of the warm busbars 340, 341, however, other mechanisms may be used to connect the cold busbars 338, 339 and the warm busbars 340, 341 using the braided links. As a result, the warm busbars 340, 341 operate at a temperature between that of the cold busbars 338, 339 (cryogenic, or warmer) and rack busbars (not shown, see e.g., rack busbars 220, 222 of FIG. 2 (room temperature, or warmer)).

A terminal end of the conductors 334, including the arrays of conductor ends 336, 337, as well as the cold busbars 338, 339, the braided links, and the warm busbars 340, 341 are all enclosed within a vacuum shell 324. The vacuum shell 324 provides a vacuum space 344 between the conductors 334, including the arrays of conductor ends 336, 337, as well as the cold busbars 338, 339, the braided links, and the warm busbars 340, 341 for thermal and/or electrical insulation from an exterior of the HTS termination 306.

The vacuum shell 324 also includes internal support structures (e.g., support structures 343, 345) made of materials with low thermal conductivity for mechanical suspension of the conductors 334, including the arrays of conductor ends 336, 337, as well as the cold busbars 338, 339, and the braided links with minimal thermal coupling between the foregoing cold masses and the warm vacuum shell 324. Parts of a cooling infrastructure, which includes but is not limited to the coolant supply 350, control valve 358, and coolant return 354 are also contained within the vacuum shell 324.

The HTS termination 306 is connected to the rack busbar(s) via an array of electrically conductive vacuum feedthroughs (e.g., vacuum feedthrough 362) that protrude through the vacuum shell 324. The conductive vacuum feedthroughs are conductive members (e.g., pin, rod, or other electrically conductive element 364), each surrounded by an insulating seal (e.g., epoxy, plastic, ceramic, or glass 366) that maintains a vacuum seal with the surrounding vacuum shell 324. The conductive vacuum feedthroughs are used to selectively connect the warm busbars 340, 341 to corresponding rack busbars through the vacuum shell 324. The conductive vacuum feedthroughs are depicted with eyelets for a mechanical and electrical connection to the rack busbars, however, the ends of the conductive vacuum feedthroughs may be of any suitable shape so that the HTS termination 306 may be screwed, bolted, or clamped to the rack busbars.

The conductive vacuum feedthroughs extending from the warm busbars 340 are illustrated in FIG. 3 without terminal ends as the cold busbar 338, associated braided links, the warm busbar 340, and the associated conductive vacuum feedthroughs are generally hidden behind the cold busbar 339, associated braided links, the warm busbar 341 and the associated conductive vacuum feedthroughs if the rack busbars extend vertically and generally parallel at a rear of the server rack, as are rack busbars 220, 222 of FIG. 2. The conductive vacuum feedthroughs may be contiguous with the warm busbars 340, 341, as shown, and thus the warm busbars 340, 341 protrudes through the vacuum shell 324 and the protruding portion(s) of the warm busbars 340, 341 selectively connects to the rack busbars directly without use of the separate conductive vacuum feedthroughs.

In the depicted two-conductor implementation (e.g., for two-phase AC or DC power delivery), the first array of conductor ends 336 forms a first conductor and the second array of conductor ends 337 forms a second conductor. The first and second arrays of conductor ends 336, 337 are connected to first and second cold busbars 338, 339. First and second arrays of braided links connect the first and second cold busbars 338, 339 to the first and second warm busbars 341, 341. The vacuum shell 324 encloses all of the foregoing. First and second arrays of vacuum feedthroughs selectively connect the first and second warm busbars 341, 341 to the rack busbar(s) through the vacuum shell 324.

In a three-conductor implementation (e.g., for three-phase AC power delivery), the third conductor is largely a duplicate of the first and second conductors, as shown in FIG. 3 and described above. An additional third array of conductor ends forms the third conductor. A third array of conductor ends is connected to a third cold busbar. A third array of braided links connects the third cold busbar to a third warm busbar. The vacuum shell 324 encloses all of the foregoing components of the third conductor as well. A third array of vacuum feedthroughs selectively connect the third warm busbar to the rack busbar(s) through the vacuum shell 324.

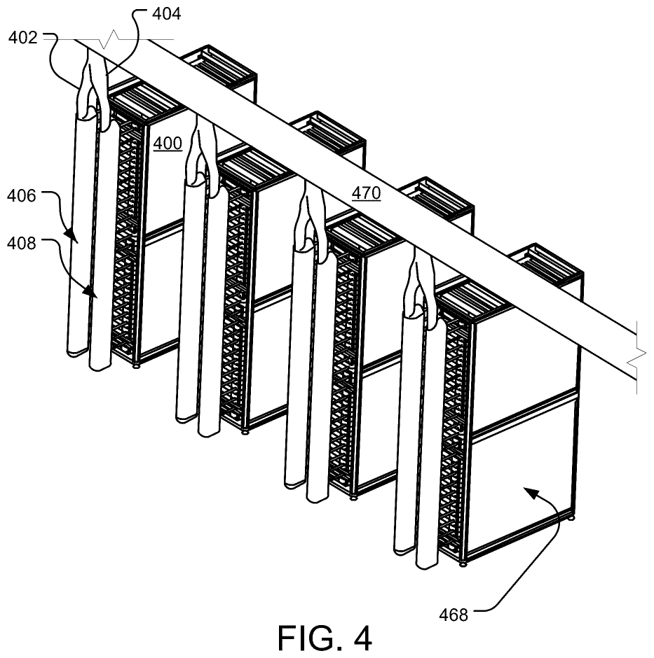

FIG. 4 illustrates a row 468 of server racks (e.g., server rack 400) connected to high-temperature superconducting (HTS) power cables (e.g., HTS power cables 402, 404) and a HTS power main 470 using example HTS terminations according to the presently disclosed technology. This is referred to herein in general as server rack power connections provided by the HTS power main 470 via the HTS power cables. The server rack 400 is a standardized frame or enclosure for mounting multiple electronic equipment modules, such as servers. The server rack 400 may be one of many within the row 468 (e.g., four server racks are depicted in row 468 of FIG. 4). Further, there may be numerous rows within a datacenter room and numerous datacenter rooms within a datacenter facility.

The HTS power main 470 extends lengthwise down the row 468, with HTS cables branching off from the HTS power main 470 to provide power to each of the server racks via HTS terminations connected to rack busbars. As a specific example, HTS power cables 402, 404 branch off from the HTS power main 470 to service server rack 400. The HTS power cables 402, 404 end with HTS terminations 406, 408, respectively. The HTS terminations 406, 408 are connected to corresponding rack busbars (not shown, see e.g., rack busbars 120, 122 of FIG. 1) that are used to power the server rack 400.

The HTS power cables 402, 404, each with associated HTS terminations 406, 408, respectively, are described separately above. In other implementations, the HTS power cables 402, 404 are combined into a singular HTS power cable and the HTS terminations 406, 408 are combined into a singular HTS termination. The combined HTS power cable and the HTS termination provides power to a singular server rack without use of another HTS power cable and HTS termination. Further, while FIG. 4 depicts one possible arrangement of an HTS power main 470 and connected HTS power cables, any configuration of HTS main(s) and connected HTS power cables is contemplated herein.

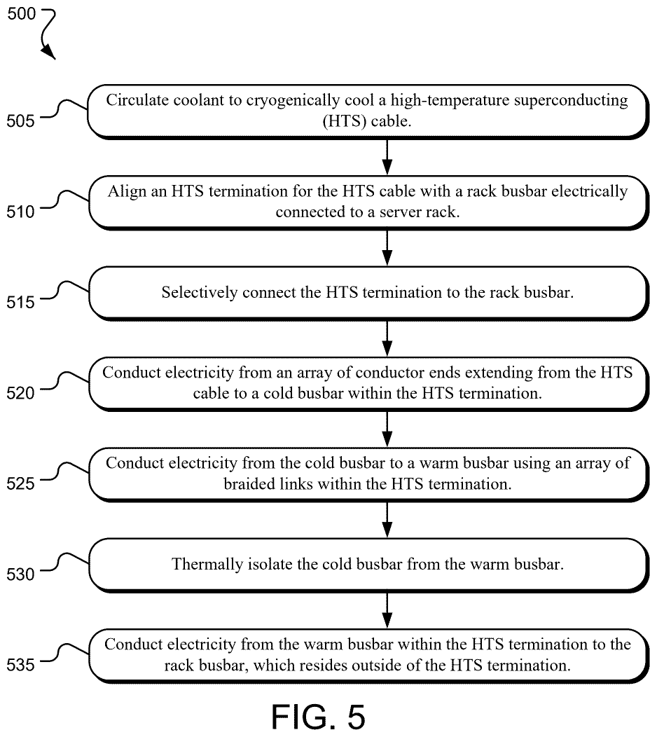

FIG. 5 illustrates example operations 500 for transmitting power from an HTS cable to a server rack using a HTS termination. The HTS cable is a cryogenically cooled power supply cable for powering the server rack with low resistance losses. The HTS termination is attached to an end of the HTS cable and serves as a device for selectively attaching the HTS cable to the server rack. The HTS termination maximizes electrical conductivity and minimizing thermal conductivity in the connection between the HTS cable and the server rack in a compact space.

A circulating operation 505 circulates coolant to cryogenically cool the HTS cable. In some implementations, the coolant has a normal boiling point below 120K. An aligning operation 510 aligns the HTS termination with a rack busbar electrically connected to the server rack. The rack busbar to power the server rack. This alignment may be accomplished using one or more matched sets of alignment pins protruding from the HTS termination and corresponding alignment apertures in the rack busbar. A selective connection operation 515 selectively connects the HTS termination to the rack busbar. This selective connection may be accomplished using a bolted or clamped connection, for example.

Once the HTS termination is connected to the rack busbar, the HTS cable may be used to conduct power to the server rack. A first conducting operation 520 conducts electricity from an array of conductor ends extending from the HTS cable to a cold busbar within the HTS termination. The array of conductor ends are soldered or otherwise directly attached to the cold busbar within the HTS termination. A second conducting operation 525 conducts electricity from the cold busbar to a warm busbar using an array of braided links connecting the cold busbar to the warm busbar within the HTS termination.

Opposing ends of the array of braided links are generally soldered or otherwise directly attached to the cold busbar and the warm busbar. The braided links are particularly effective at conducting electricity and limiting thermal conduction. Thus, the braided links perform a thermally isolating operation 530 that thermally isolates the cold busbar from the warm busbar. The thermally isolating operation 530 is also performed by a vacuum shell that encloses the array of conductor ends, the cold busbar, the warm busbar, and the array of braided links within the HTS termination. A defined internal space between the vacuum shell and the components it encloses minimizes thermal transfer between the components of the HTS termination excepting the conductive pathways required to conduct electricity through the HTS termination.

A third conducting operation 535 conducts electricity from the warm busbar within the HTS termination to the rack busbar, which resides outside of the HTS termination. The foregoing selective connection operation 515 selectively connects the warm busbar to the rack busbar through the vacuum shell. In one implementation, an array of vacuum feedthroughs protrude from the HTS termination through its vacuum shell. The vacuum feedthroughs are then used to selectively connect the warm busbar to the rack busbar per the foregoing selective connection operation 515. In another implementation, the warm busbar itself protrudes from the HTS termination through its vacuum shell. A protruding portion of the warm busbar itself is used to selectively connect the warm busbar to the rack busbar per the foregoing selective connection operation 515.

In sum, the conducting operations 520, 525, 535 conduct power supplied by the HTS cable to the server rack to power the server rack with minimal resistance losses. The HTS termination serves to electrically connect the HTS cable to the server rack and thermally isolate the HTS cable from the server rack, all within a package that may be attached to the rear of the server rack. Multiples of the HTS cable and the server rack may be used within a datacenter to scale the foregoing disclosed technology up.

Methods and operations described herein may be referred to variously as operations, method steps, objects, or modules. The operations may be performed in any order, adding or omitting operations as desired, unless explicitly claimed otherwise or a specific order is inherently necessitated by the claim language.

Implementations disclosed herein include a high-temperature superconducting (HTS) termination comprising an HTS cable including a first array of conductor ends; a first cold busbar, the first array of conductor ends connected to the first cold busbar; a first warm busbar; a first array of braided links connecting the first cold busbar to the first warm busbar; and a vacuum shell enclosing the first array of conductor ends, the first cold busbar, the first warm busbar, and the first array of braided links.

The HTS cable may include a second array of conductor ends. The HTS termination may further comprise a second cold busbar, the second array of conductor ends connected to the second cold busbar; a second warm busbar; and a second array of braided links connecting the second cold busbar to the second warm busbar, wherein the vacuum shell further encloses the second array of conductor ends, the second cold busbar, the second warm busbar, and the second array of braided links.

The first array of conductor ends may form a first conductor, and the second array of conductor ends may form a second conductor for a two-conductor power connection.

The HTS cable may include a third array of conductor ends. The HTS termination may further comprise a third cold busbar, the third array of conductor ends connected to the third cold busbar; a third warm busbar; and a third array of braided links connecting the third cold busbar to the third warm busbar, wherein the vacuum shell further encloses the third array of conductor ends, the third cold busbar, the third warm busbar, and the third array of braided links.

The first array of conductor ends may form a first conductor, the second array of conductor ends may form a second conductor, and the third array of conductor ends may form a third conductor for a three-conductor power connection.

The HTS termination may further comprise an array of vacuum feedthroughs to selectively connect the first warm busbar to a rack busbar through the vacuum shell.

The first warm busbar may protrude from the vacuum shell, a protruding portion of the first warm busbar to selectively connect to a rack busbar.

The HTS termination may further comprise a rack busbar, the first warm busbar to selectively connect to the rack busbar.

One of the first warm busbar and the rack busbar may include one or more alignment pins and the other of the first warm busbar and the rack busbar may include one or more corresponding alignment apertures, wherein the alignment pins and corresponding alignment apertures align the first warm busbar to the rack busbar.

The first warm busbar may be selectively clamped or bolted to the rack busbar.

The vacuum shell may include a support structure for the first array of conductor ends and a cooling infrastructure.

Implementations further disclosed herein include a method of transmitting power from a high-temperature superconducting (HTS) cable to a server rack using a HTS termination. The method may comprise conducting electricity from an array of conductor ends extending from the HTS cable to a cold busbar within the HTS termination; conducting electricity from the cold busbar to a warm busbar using an array of braided links connecting the cold busbar to the warm busbar within the HTS termination, wherein a vacuum shell encloses the array of conductor ends, the cold busbar, the warm busbar, and the array of braided links within the HTS termination; and conducting electricity from the warm busbar within the HTS termination to a rack busbar outside of the HTS termination, the rack busbar to power the server rack.

The method may further comprise thermally isolating the cold busbar from the warm busbar using the array of braided links.

The method may further comprise aligning the HTS termination with the rack busbar and selectively connecting the warm busbar to the rack busbar through the vacuum shell.

The array of vacuum feedthroughs may selectively connect the warm busbar to the rack busbar through the vacuum shell.

The warm busbar may protrude through the vacuum shell, a protruding portion of the warm busbar selectively connecting to the rack busbar.

The method may further comprise circulating coolant to cryogenically cool the HTS cable.

Implementations further disclosed herein include a server rack power connection comprising a high-temperature superconducting (HTS) power cable, an HTS termination to receive an array of conductor ends from the HTS power cable, and one or more servers to be powered by the HTS power cable. The HTS power cable includes an arrangement of conductors extending lengthwise down the HTS power cable, a coolant supply extending lengthwise down the HTS power cable and in thermally conductive contact with the arrangement of conductors, a coolant return extending lengthwise down the HTS power cable, a vacuum jacket extending lengthwise down the HTS power cable and surrounding the arrangement of conductors, coolant supply, and the coolant return, and an array of conductor ends extending from a terminal end of the arrangement of conductors. The HTS termination includes a cold busbar, the array of conductor ends connected to the cold busbar; a warm busbar; an array of braided links connecting the cold busbar to the warm busbar; a vacuum shell enclosing the conductor ends, the cold busbar, the warm busbar, and the array of braided links; and an array of vacuum feedthrough pins protruding through the vacuum shell. The server rack includes one or more servers and a rack busbar, wherein the vacuum feedthrough pins selectively connect the warm busbar to the rack busbar through the vacuum shell.

One of the warm busbar and the rack busbar may include one or more alignment pins and the other of the warm busbar and the rack busbar may include one or more corresponding alignment apertures, wherein the alignment pins and corresponding alignment apertures align the warm busbar to the rack busbar.

The server rack power connection may further comprise an HTS power main, wherein the HTS power cable branches off from the HTS power main.

The above specification, examples, and data provide a complete description of the structure and use of exemplary implementations of the presently disclosed technology. Since many implementations can be made without departing from the spirit and scope of the presently disclosed technology, the scope resides in the claims hereinafter appended. Furthermore, structural features of the different implementations may be combined in yet another implementation without departing from the recited claims.

What is claimed is:

1. A high-temperature superconducting (HTS) termination comprising:
an HTS cable including a first array of conductor ends;
a first cold busbar, the first array of conductor ends connected to the first cold busbar;
a first warm busbar;
a first array of braided links connecting the first cold busbar to the first warm busbar; and
a vacuum shell enclosing the first array of conductor ends, the first cold busbar, the first warm busbar, and the first array of braided links.

2. The HTS termination of claim 1, wherein the HTS cable includes a second array of conductor ends, the HTS termination further comprising:
a second cold busbar, the second array of conductor ends connected to the second cold busbar;
a second warm busbar; and
a second array of braided links connecting the second cold busbar to the second warm busbar, wherein the vacuum shell further encloses the second array of conductor ends, the second cold busbar, the second warm busbar, and the second array of braided links.

3. The HTS termination of claim 2, wherein the first array of conductor ends form a first conductor and the second array of conductor ends form a second conductor for a two-conductor power connection.

4. The HTS termination of claim 2, wherein the HTS cable includes a third array of conductor ends, the HTS termination further comprising:
a third cold busbar, the third array of conductor ends connected to the third cold busbar;
a third warm busbar; and
a third array of braided links connecting the third cold busbar to the third warm busbar, wherein the vacuum shell further encloses the third array of conductor ends, the third cold busbar, the third warm busbar, and the third array of braided links.

5. The HTS termination of claim 4, wherein the first array of conductor ends form a first conductor, the second array of conductor ends form a second conductor, and the third array of conductor ends form a third conductor for a three-conductor power connection.

6. The HTS termination of claim 1, further comprising:
an array of vacuum feedthroughs to selectively connect the first warm busbar to a rack busbar through the vacuum shell.

7. The HTS termination of claim 1, wherein the first warm busbar protrudes from the vacuum shell, a protruding portion of the first warm busbar to selectively connect to a rack busbar.

8. The HTS termination of claim 1, further comprising:
a rack busbar, the first warm busbar to selectively connect to the rack busbar.

9. The HTS termination of claim 8, wherein one of the first warm busbar and the rack busbar includes one or more alignment pins and the other of the first warm busbar and the rack busbar includes one or more corresponding alignment apertures, wherein the alignment pins and corresponding alignment apertures align the first warm busbar to the rack busbar.

10. The HTS termination of claim 8, wherein the first warm busbar is selectively clamped or bolted to the rack busbar.

11. The HTS termination of claim 1, wherein the vacuum shell includes a support structure for the first array of conductor ends and a cooling infrastructure.

12. A method of transmitting power from an high-temperature superconducting (HTS) cable to a server rack using a HTS termination comprising:
conducting electricity from an array of conductor ends extending from the HTS cable to a cold busbar within the HTS termination;
conducting electricity from the cold busbar to a warm busbar using an array of braided links connecting the cold busbar to the warm busbar within the HTS termination, wherein a vacuum shell encloses the array of conductor ends, the cold busbar, the warm busbar, and the array of braided links within the HTS termination; and
conducting electricity from the warm busbar within the HTS termination to a rack busbar outside of the HTS termination, the rack busbar to power the server rack.

13. The method of claim 12, further comprising:
thermally isolating the cold busbar from the warm busbar using the array of braided links.

14. The method of claim 12, further comprising:
aligning the HTS termination with the rack busbar; and
selectively connecting the warm busbar to the rack busbar through the vacuum shell.

15. The method of claim 14, wherein an array of vacuum feedthroughs selectively connects the warm busbar to the rack busbar through the vacuum shell.

16. The method of claim 14, wherein the warm busbar protrudes through the vacuum shell, a protruding portion of the warm busbar selectively connects to the rack busbar.

17. The method of claim 12, further comprising:
circulating coolant to cryogenically cool the HTS cable.

18. A server rack power connection comprising:
a high-temperature superconducting (HTS) power cable including:
an arrangement of conductors extending lengthwise down the HTS power cable;
a coolant supply extending lengthwise down the HTS power cable and in thermally conductive contact with the arrangement of conductors;
a coolant return extending lengthwise down the HTS power cable;
a vacuum jacket extending lengthwise down the HTS power cable and surrounding the arrangement of conductors, coolant supply, and the coolant return; and
an array of conductor ends extending from a terminal end of the arrangement of conductors;
a HTS termination to receive the array of conductor ends from the HTS power cable, the HTS termination including:
a cold busbar, the array of conductor ends connected to the cold busbar;
a warm busbar;
an array of braided links connecting the cold busbar to the warm busbar;
a vacuum shell enclosing the conductor ends, the cold busbar, the warm busbar, and the array of braided links; and
an array of vacuum feedthrough pins protruding through the vacuum shell; and
a server rack to be powered by the HTS power cable, the server rack including:
one or more servers; and
a rack busbar, wherein the vacuum feedthrough pins selectively connect the warm busbar to the rack busbar through the vacuum shell.

19. The server rack power connection of claim 18, wherein one of the warm busbar and the rack busbar includes one or more alignment pins and the other of the warm busbar and the rack busbar includes one or more corresponding alignment apertures, wherein the alignment pins and corresponding alignment apertures align the warm busbar to the rack busbar.

20. The server rack power connection of claim 18, further comprising:
an HTS power main, wherein the HTS power cable branches off from the HTS power main.
